(19) United States
(12) Patent Application Publication
(10) Pub. No.: US 2019/0228992 A1
(43) Pub. Date: Jul. 25, 2019

(54) SUBSTRATE PROCESSING METHOD AND SUBSTRATE PROCESSING SYSTEM

(71) Applicant: TOKYO ELECTRON LIMITED, Tokyo (JP)

(72) Inventors: Masami OIKAWA, Oshu City (JP); Keisuke FUJITA, Nirasaki City (JP)

(21) Appl. No.: 16/251,958

(22) Filed: Jan. 18, 2019

(30) Foreign Application Priority Data
Jan. 19, 2018 (JP) 2018-007674

(51) Int. Cl. H01L 21/67; H01L 21/673; H01L 21/3065

(52) U.S. Cl. CPC H01L 21/67069; H01L 21/3065; H01L 21/67303

(57) ABSTRACT

There is provided a substrate processing method comprising etching a silicon film formed on a surface of a substrate accommodated in a processing container by supplying an etching gas to the substrate, purging the processing container by supplying a hydrogen-containing gas that reacts with the etching gas as a purge gas into the processing container, and forming an additional silicon film on the substrate.

### CROSS-REFERENCE TO RELATED APPLICATION

This application is based upon and claims the benefit of priority from Japanese Patent Application No. 2018-007674, filed on Jan. 19, 2018, the entire contents of which are incorporated herein by reference.

### TECHNICAL FIELD

The present disclosure relates to a substrate processing method and a substrate processing system.

### BACKGROUND

In the related art, a method is known in which an etching gas is supplied to a wafer contained in a processing container and a silicon film formed on the wafer is selectively etched. As an example of an etching gas, a halogen gas containing a halogen element such as fluorine (F) or bromine (Br) is used in consideration of the fact that a silicon film can be removed with a highly volatile halogen compound.

### SUMMARY

However, when an etching gas such as a halogen gas remains in a processing container, there is a possibility that an incubation time is prolonged (film formation deteriorates) and the roughness of a film formation surface increases when a film formation step is performed following an etching step.

The present disclosure has been made in view of the above problems, and the present disclosure provides a substrate processing method and a substrate processing system capable of effectively purging an etching gas from a processing container.

According to one embodiment of the present disclosure, there is provided a substrate processing method including: etching a silicon film formed on a surface of a substrate accommodated in a processing container by supplying an etching gas to the substrate; purging the processing container by supplying a hydrogen-containing gas that reacts with the etching gas as a purge gas into the processing container; and forming an additional silicon film on the substrate.

According to one embodiment of the present disclosure, there is provided a substrate processing system that accommodates a substrate to form a silicon film, the substrate processing system including: a processing container configured to accommodate the substrate therein; a processing apparatus having a gas supply part configured to supply a processing gas into the processing container; and a control device configured to control at least the gas supply part, wherein the control device is configured to: execute a process of etching all or a part of the silicon film by supplying an etching gas to the substrate having the silicon film on a surface thereof, perform a process of purging by supplying a hydrogen-containing gas that reacts with the etching gas as a purge gas into the processing container, and perform a process of forming an additional silicon film on the substrate by supplying a raw material gas to the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating an example of the overall configuration of a substrate processing system according to an embodiment of the present disclosure.

FIG. 2 is a view illustrating an example of a hardware configuration of a control device constituting a substrate processing system.

FIG. 3 is a view illustrating an example of a functional configuration of a control device constituting a substrate processing system.

FIGS. 4A to 4F are process cross-sectional views for explaining an example of a substrate processing method according to an embodiment of the present disclosure.

FIG. 5 is a view illustrating an experimental result verifying an incubation time by a purge step after an etching step.

FIG. 6 is a view illustrating an experimental result verifying an improvement in roughness of a silicon film by a purge step after an etching step.

### DETAILED DESCRIPTION

Hereinafter, a substrate processing method and a substrate processing system according to an embodiment of the present disclosure will be described with reference to the accompanying drawings. In the specification and drawings, constituent elements that are substantially the same will be denoted by the same reference numerals, and redundant descriptions will be omitted.

[Substrate Processing System According to Embodiment]

<Substrate Processing Apparatus>

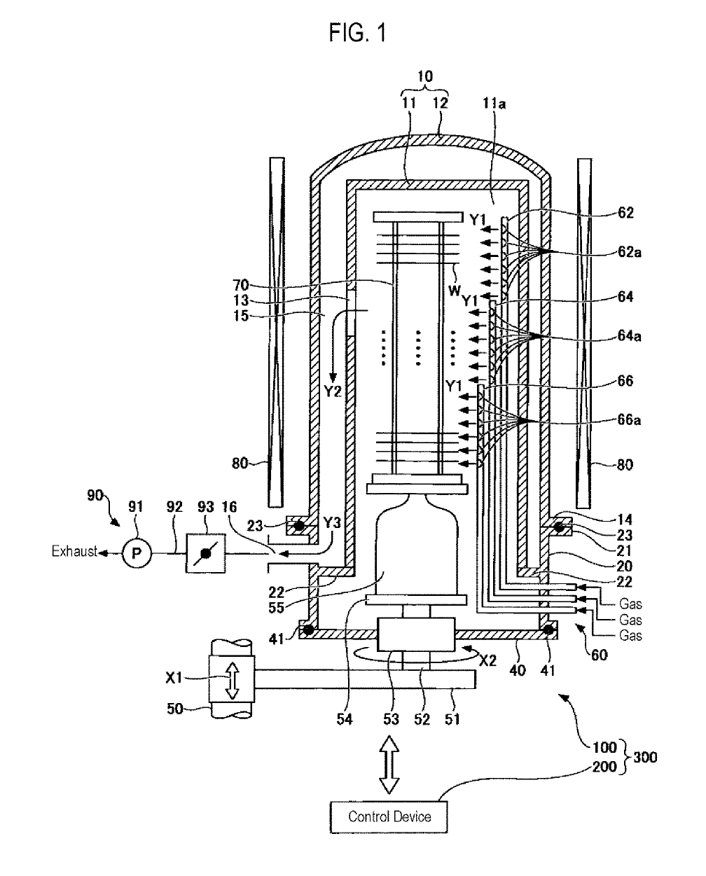

First, the overall configuration of a substrate processing system according to an embodiment of the present disclosure will be schematically described, and a substrate processing apparatus that constitutes the substrate processing system will be described. FIG. 1 is a cross-sectional view illustrating an example of the overall configuration of a substrate processing system according to an embodiment of the present disclosure. As illustrated in FIG. 1, a substrate processing system 300 includes a processing apparatus 100, which is a batch-type vertical film formation apparatus, and a control device 200.

The processing apparatus 100 includes a processing container 10, a heater 80 surrounding the processing container 10 outside the processing container 10, a gas supply part 60 configured to supply various gases into the processing container 10, and a gas exhaust part 90 configured to exhaust a gas from the processing container 10. Further, the processing apparatus 100 includes a wafer boat 70 configured to hold a plurality of semiconductor wafers as substrates (hereinafter, referred to as “wafers”) in a vertical direction at a predetermined interval, and a boat elevator 50 configured to load and unload the plurality of wafers W into and from the processing container 10 by raising and lowering the wafer boat 70 in a direction X1.

The processing container 10 has a cylindrical inner processing tube 11 (inner tube) having a ceiling and an opened lower end and a cylindrical outer processing tube 12 (outer tube) having an opened lower end and a ceiling to cover the outside of the inner processing tube 11. Both the inner processing tube 11 and the outer processing tube 12 are formed of a heat-resistant material such as quartz, and are arranged coaxially to form a double-tube structure.

The ceiling of the inner processing tube 11 is formed so as to be, for example, flat. In one region of the inner side of the inner wall surface of the cylindrical inner processing tube 11, there is provided an injector arrangement region 11a in which injectors are arranged, and in the other region opposite the injector arrangement region 11a, there is provided a gas exhaust port 13 to exhaust a gas to the outside of the inner processing tube 11. The gas exhaust port 13 is an exhaust port that mainly exhausts the processing gas in the inner processing tube 11, and the vertical length thereof may be appropriately set. As in the example illustrated in the drawing, the length of the gas exhaust port 13 may be shorter than the vertical length of the wafer boat 70, or may be approximately equal to the vertical length of the wafer boat 70.

The lower ends of the inner processing tube 11 and the outer processing tube 12 forming the processing container 10 are supported by a cylindrical manifold 20 formed of, for example, stainless steel. At the upper end of the cylindrical manifold 20, an annular flange 21 protrudes to the outside to support the outer processing tube 12. Further, below the manifold 20, an annular flange 22 protrudes inwards to support the inner processing tube 11. The lower end of the inner processing tube 11 is placed on the annular flange 22, and the annular flange 14 at the lower end of the outer processing tube 12 is placed on and supported by the annular flange 21. A seal member 23 such as an O-ring is interposed between the annular flange 21 of the manifold 20 and the annular flange 14 of the outer processing tube 12 and the outer processing tube 12 and the manifold 20 are airtightly connected to each other.

A lid 40 is airtightly attached to the opening in the lower end of the cylindrical manifold 20, with a sealing member 41 such as an O-ring interposed therebetween, and airtightly closes the opening in the lower end of the processing container 10. The lid 40 is formed of, for example, stainless steel.

A magnetic fluid seal member 53 is attached to the central portion of the lid 40, and a rotary shaft 52 passes through (is loosely fitted to) the magnetic fluid seal member 53 in a rotatable and airtight state. The lower end of the rotary shaft 52 is rotatably supported by a support arm 51 extending laterally from the boat elevator 50, which is an elevating mechanism, and is rotatable in the X2 direction by an actuator such as a motor.

A rotary plate 54 is disposed on the upper end of the rotary shaft 52, and a heat-insulating cylinder 55 made of quartz is mounted on the rotary plate 54. The wafer boat 70, which holds a plurality of wafers W aligned at a predetermined interval in the vertical direction, is placed on the heat-insulating cylinder 55. With this configuration, when the boat elevator 50 is raised and lowered in the direction X1, the wafer boat 70 is raised and lowered integrally via the support arm 51, the rotary plate 54, and the heat-insulating cylinder 55, and the wafer boat 70 is loaded and unloaded into and from the processing container 10. Further, it is possible to rotate the wafer boat 70 by rotating the rotary shaft 52.

The gas supply part 60 includes a plurality of gas supply sources (not illustrated) and a plurality of (e.g., three, as in the illustrated example) injectors 62, 64, and 66 that are in fluid communication with the plurality of gas supply sources via a control valve (not illustrated). The respective injectors 62, 64, and 66 are arranged in the longitudinal direction (vertical direction) of the inner processing tube 11 inside the inner wall of the inner processing tube 11, and the base ends thereof are bent in an L shape to extend to the corresponding gas supply sources through the lateral side of the manifold 20.

The injectors 62, 64, and 66 are disposed at intervals inside the inner wall of the inner processing tube 11 so as to be aligned in a row in the circumferential direction, and the vertical lengths thereof are set to be shorter in the order of the injectors 62, 64, and 66.

In order to supply a processing gas to the upper region of the inner processing tube 11, a plurality of gas holes 62a are provided in the longest injector 62 at predetermined intervals in the longitudinal direction within a predetermined range in the upper portion of the longest injector 62, so that various processing gases can be supplied horizontally in the direction Y1 through the gas holes 62a. On the other hand, in order to supply a processing gas to the middle region of the inner processing tube 11, a plurality of gas holes 64a are provided in the injector 64 at predetermined intervals in the longitudinal direction within a predetermined range in the upper portion of the injector 64, so that various processing gases can be supplied horizontally in the direction Y1 through the gas holes 64a. In addition, in order to supply a processing gas to the lower region of the inner processing tube 11, a plurality of gas holes 66a are provided in the injector 66 at predetermined intervals in the longitudinal direction within a predetermined range in the upper portion of the injector 66, so that various processing gases can be supplied horizontally in the direction Y1 through the gas holes 66a. In this way, it is possible to independently supply various processing gases to the upper portion, the central portion, and the lower portion in the inner processing tube 11 using respective injectors 62, 64, and 66.

The illustrated processing apparatus 100 is a so-called side-flow-type processing apparatus that supplies various kinds of processing gases horizontally from the lateral side inside the inner processing tube 11 in the processing container 10. For example, the processing apparatus may be a so-called normal-flow-type processing apparatus that blows and supplies various kinds of processing gases upwards from the lower side of the inner processing tube 11. When supplying the processing gases to each wafer W by using the side-flow-type processing apparatus 100, as in the illustrated example, by rotating the wafer boat 70 in the direction X2, it becomes possible to supply the processing gases to the entire surface of each wafer W. Further, unlike the illustrated processing apparatus 100, a side-flow-type processing apparatus may be adopted, in which a plurality of injectors having the same vertical length is provided, and each injector has a plurality of gas holes, which is capable of supplying a processing gas from the lower end to the upper end of the wafer boat 70 at predetermined intervals, thereby simultaneously supplying the processing gas from the respective gas holes in the respective injectors. Further, a processing apparatus having only one injector may be adopted. In addition, a control method in which the same processing gas is supplied from a plurality of injectors for each process may be applied. Further, in the processing apparatus having a plurality of injectors of the same length, a control method in which different kinds of processing gases are supplied from each injector in each process may be applied.

The processing gases supplied from the respective gas holes 62a, 64a, and 66a in the injectors 62, 64, and 66 may be various kinds of processing gases such as a film formation gas (a row material gas), an etching gas, a purge gas, an oxidizing gas, a nitriding gas, a reducing gas and the like. Specific examples of processing gases will be described in detail in the following description of the substrate processing method.

A gas exhaust port 16 is formed above the side wall of the manifold 20, and the gas exhaust port 16 communicates with a gas flow space 15 between the inner processing tube 11 and the outer processing tube 12. For example, a processing gas supplied from the gas holes 62a and the like of the injector 62 circulates in the inner processing tube 11 in the horizontal direction, then flows in the gas flow space 15 in the direction Y2, flows into the gas exhaust port 16 in the direction Y3, and is exhausted outside the apparatus. The gas exhaust port 16 is provided with the gas exhaust part 90. The gas exhaust part 90 includes an exhaust flow path 92 configured to communicate with the gas exhaust port 16, a vacuum pump 91 configured to execute vacuum suction of a processing gas at a downstream end of the exhaust flow path 92, and a pressure-regulating valve 93 configured to execute pressure regulation at the time of suction at an intermediate position of the exhaust flow path 92.

<Control Device>

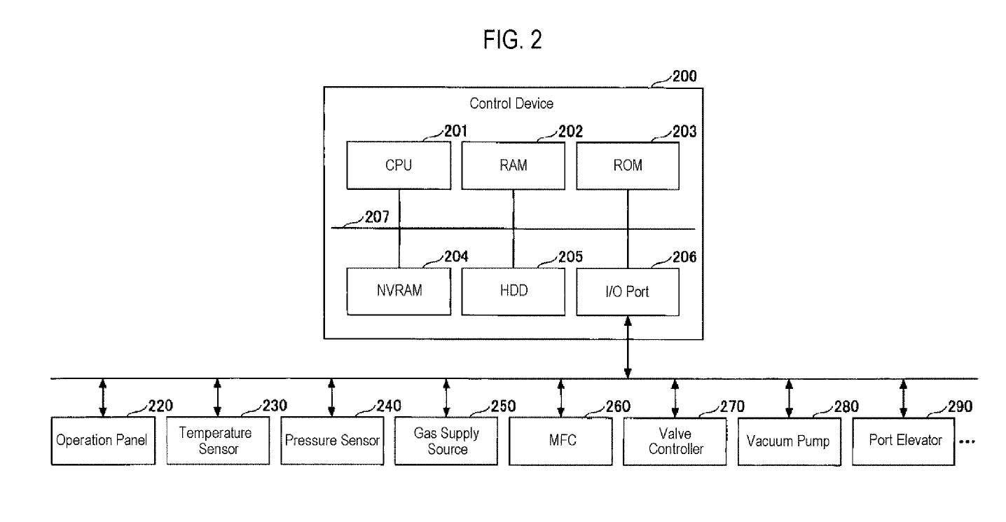

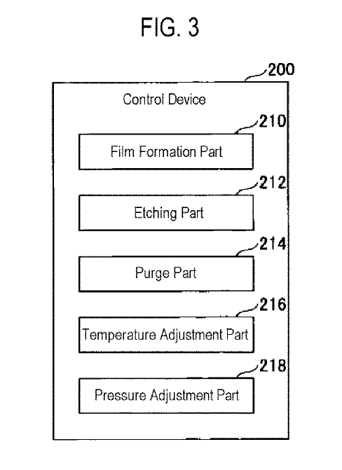

Next, the control device constituting the substrate processing system will be described. FIG. 2 is a view illustrating an example of the hardware configuration of a control device, and FIG. 3 is a view showing an example of the functional configuration of the control device.

The control device 200 is constituted with a computer, and includes a Central Processing Unit (CPU) 201, a Random-Access Memory (RAM) 202, a Read-Only Memory (ROM) 203, a Non-Volatile RAM (NVRAM) 204, a Hard Disk Drive (HDD) 205, an I/O port 206, and the like, as illustrated in FIG. 2. The respective parts are connected to each other by a bus 207 so that information can be transmitted therebetween.

The ROM 203 stores various programs, data used by the programs, and the like. The RAM 202 is used as a storage area for loading programs or as a work region for loaded programs. The CPU 201 implements various functions by processing the programs loaded in the RAM 202. The HDD 205 stores programs and various kinds of data used by the programs. The NVRAM 204 stores various kinds of setting information and the like.

The HDD 205 stores various kinds of sequence information, such as a temperature condition, a pressure condition, a process time, or the like regarding each process such as a film formation step, an etching step, a purging step, or the like. In addition, for example, a temperature change, a pressure change, a start time or stop time of supply of a processing gas, and a supply amount of the processing gas in each region in the inner processing tube 11 from the time of loading of a predetermined number of wafers W to the processing apparatus 100 until the processed wafers W are unloaded, are specified in detail.

The I/O port 206 is connected to an operation panel 220, a temperature sensor 230, a pressure sensor 240, a gas supply source 250, a Mass Flow Controller (MFC) 260, a valve controller 270, a vacuum pump 280, a boat elevator drive mechanism 290, and the like, and controls input and output of various data and signals.

The CPU 210 functions as a main part of the control device 200, and executes a control program stored in the ROM 203 or the like. Further, the CPU 210 controls the operation of each part constituting the processing apparatus 100 according to a recipe (process recipe) stored in the HDD 205 on the basis of an instruction signal from the operation panel 220. That is, the CPU 210 causes the temperature sensor (group) 230, the pressure sensor (group) 240, the gas supply source (group) 250, MFC 260 and the like to measure the temperature, the pressure, the flow rate, and the like of each part, for example, inside the inner processing tube 11 and inside the exhaust flow path 92. Based on these measurement data, the CPU 210 outputs control signals to the MFC 260, the valve controller 270, the vacuum pump 280, and the like, so that each of the above parts follows the process recipe.

As illustrated in FIG. 3, the control device 200 also includes a film formation part 210, an etching part 212, a purge part 214, a temperature adjustment part 216, a pressure adjustment part 218, and the like.

The film formation part 210 supplies various raw material gases to the surface of a wafer W so as to form a silicon film (Si film) composed of amorphous silicon or the like, or an insulating film of SiO₂, SiN, or the like. A Chemical Vapor Deposition (CVD) method, an Atomic Layer Deposition (ALD) method, a Molecular Layer Deposition (MLD) method, or the like may be applied as a method of forming the silicon film, the insulating film, and the like. In the film formation by the film formation part 210, different silicon-containing gases (Si raw material gases) may be sequentially supplied to the wafer W in accordance with a set process recipe so as to sequentially form silicon films.

In the step of forming a predetermined silicon film on, for example, the surface of the wafer W, the etching part 212 supplies an etching gas composed of a halogen gas or the like to the wafer W in accordance with a process recipe so as to etch a part or all of the silicon film.

The purge part 214 purges the supplied raw material gas, etching gas, and the like out of the processing container 10 according to the process recipe during a main step, such as the film formation step and the etching step, or throughout all the steps. An inert gas such as nitrogen (N₂) gas or the like may be supplied into the processing container 10 through the purge part 214, for example, throughout all the steps other than the etching step and the film formation step. However, the purge part 214 according to the present embodiment has a function of supplying a hydrogen-containing gas into the processing container 10, in particular, after the etching step.

In the control device 200, a process recipe is set in which, particularly after the etching step, a hydrogen-containing gas is supplied as a purge gas into the processing container 10 to react with the etching gas so as to purge the etching gas, and thereafter a film formation gas is supplied so as to form a silicon film. The etching part 212, the purge part 214, and the film formation part 210 functions according to the process recipe set as described above.

The temperature adjustment part 216 adjusts the temperature of each wafer W placed in the processing container 10, more precisely, in the wafer boat 70, such that the temperature according to the process recipe is obtained for each of the various processes. For example, in the case of forming a silicon film by sequentially supplying different raw material gases in the film formation step, the temperature inside the processing container 10 is adjusted by the temperature adjustment part 216 such that the wafer W has a temperature according to the process recipe for each raw material gas.

The pressure adjustment part 218 adjusts the pressure in the processing container 10 such that the pressure according to the process recipe is obtained for each of various processes. For example, in the film formation step, in the case of forming a silicon film by sequentially supplying different raw material gases, the pressure inside the processing container 10 is adjusted by the pressure adjustment part 218 such that the inside of the processing container 10 has the pressure according to the process recipe for each raw material gas. In the purge process, in order to purge the raw material gas, the etching gas, and the like supplied into the processing container 10 in the preceding process within a predetermined time, the vacuum suction force of the vacuum pump 280 is adjusted by the pressure adjustment part 218.

By including the etching part 212, the purge part 214 that supplies a hydrogen-containing gas as a purge gas that reacts with the etching gas, into the processing container 10, and the film formation part 210 that newly forms a silicon film on a wafer W, the control device 200 is capable of performing the next film formation subsequent to sufficiently purging the etching gas from the processing container. Therefore, when a series of steps described above are performed in the same processing container 10, problems such as prolongation of an incubation time (deterioration of film formation) and increase of roughness of the film formation surface in the film formation step following the etching step are suppressed.

[Substrate Processing Method According to Embodiment]

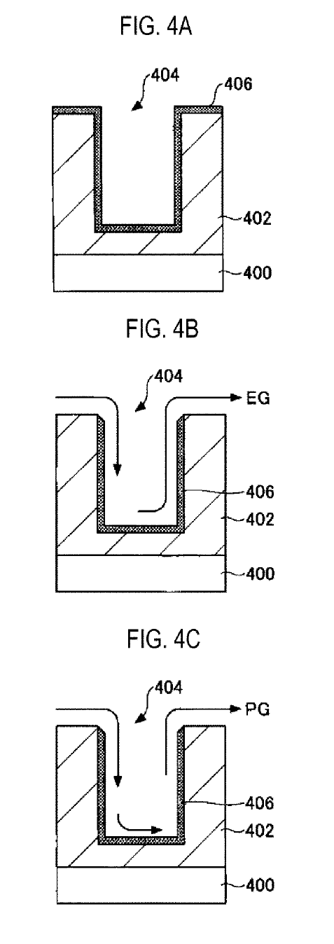

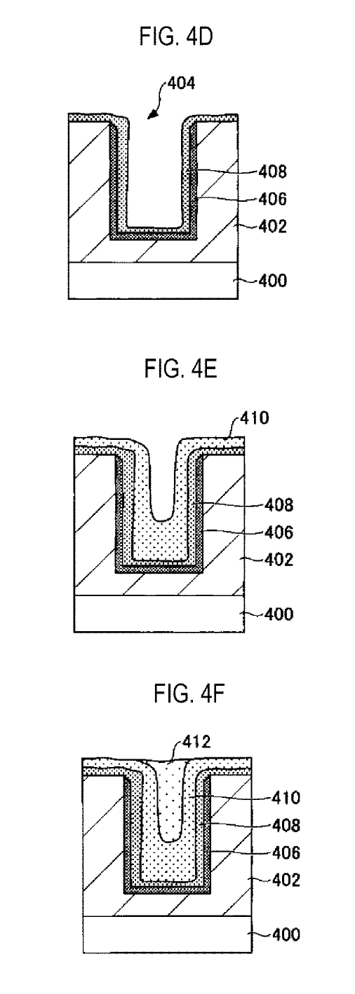

Next, a substrate processing method according to an embodiment of the present disclosure will be described. FIGS. 4A to 4F are process cross-sectional views for explaining an example of a substrate processing method, and the processes from FIG. 4A to FIG. 4F form a series of sequence.

First, as illustrated in the step of FIG. 4A, a wafer 400 in which an insulating film 402 composed of a SiO2 film, a SiN film, or the like, in which a recess 404 such as a trench or a hole is formed in a predetermined pattern, is provided, wherein a first silicon film 406 composed of amorphous silicon has already been formed in the recess 404, is loaded into the processing container 10.

Here, as a raw material gas for forming the first silicon film 406 composed of amorphous silicon, a silane compound or an aminosilane compound may be used. As the silane compound, for example, disilane (Si₂H₆) may be used. As the aminosilane compound, for example, butylamino silane (BAS), bis(tertiary-butylamino)silane (BTBAS), dimethylamino silane (DMAS), bis(dimethylamino)silane (BDMAS), dipropylamine silane (DPAS), and diisopropylamino silane (DIPAS) may be used. When filling the recess 404 with an amorphous silicon film or the like in the state in which voids or the like are not interposed if possible, a so-called seed layer formed of dimethylamino silane, disilane, or the like may be formed on the surface of the recess 404. As an example of the dimensions of the recess 404, for example, an opening diameter or an opening width is 5 to 40 nm, and a depth is 50 to 300 nm.

Next, as illustrated in the step of FIG. 4B, an etching gas EG composed of a halogen gas is supplied to the wafer W, and a part of the first silicon film 406 is etched (etching step). As the etching gas composed of a halogen gas, for example, Cl₂, HCl, F₂, Br₂, HBr, or the like may be used, among which Cl₂ gas or HBr gas having good etching controllability is preferable. In the step of FIG. 4B, the first silicon film 406 remains from the side surface to the bottom portion of the recess 404. However, the etching may be performed so as to have the first silicon film 406 remain only in the bottom portion. Various forms of etching may be possible. Here, as the process conditions in the etching step, the temperature in the processing container 10 is in the range of 200 to 800 degrees C. and the pressure is in the range of 10 to 30 Torr (1334 to 4002 Pa).

Next, as illustrated in the step of FIG. 4C, as a purge gas PG reacting with the etching gas, a hydrogen-containing gas is supplied to the wafer W to purge (purge step). Here, as the hydrogen-containing gas, which reacts with the etching gas composed of the halogen gas, any one of H₂ gas and NH₃ gas is preferable from the viewpoint of reactivity with the etching gas. Here, as the process conditions in the purge step, the temperature in the processing container 10 is in the range of 400 to 900 degrees C. and the pressure is in the range of 50 to 100 Torr (6670 to 3340 Pa).

Next, as illustrated in the step of FIG. 4D, a second silicon film 408, which is a seed layer, is further formed on the surface of the first silicon film 406, which is the seed layer subjected to etching. For example, after forming the first silicon film 406 using dimethylamino silane, the second silicon film may be formed using disilane. In the step where the first silicon film 406 and the second silicon film 408, which are two seed layers, are formed in the recess 404, the recess 404 is not completely closed with the silicon films.

Therefore, by forming the third silicon films 410 and 412, which are thick films, by sequentially supplying raw material gases of the same material to the wafer 400 through the step of FIG. 4E and then the step of FIG. 4F, the recess 404 is closed (the steps of FIGS. 4D to 4F are the film formation steps). For example, after forming the first silicon film 406 using dimethylamino silane and forming the second silicon film using disilane, the third silicon film may be formed using monosilane (SiH₄).

As described above, problems such as prolongation of the incubation time in the film formation step and increase of roughness of the film formation surface are suppressed by performing the substrate processing method such that a purge step of supplying a hydrogen-containing gas as the purge gas reacting with the etching gas is performed after the etching step, and then the film formation step is performed in the same processing container 10.

<Experiment of Verifying Incubation Time and Result Thereof>

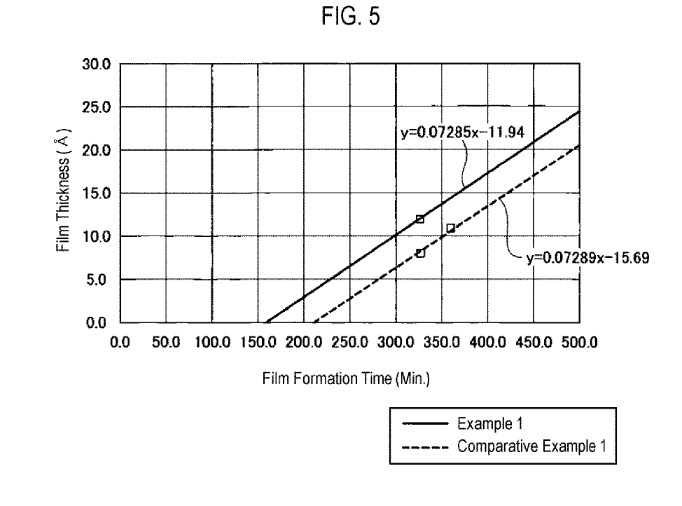

After performing etching on wafers, on which the film formation processing is underway, using HBr gas, the present inventors conducted experiments of two cases to verify the incubation time thereof. One is a case in which purging was performed using NH₃ gas and then film formation was performed as Example 1, and the other is a case in which film formation was performed without performing purging as Comparative Example 1. The experimental results are represented in FIG. 5.

From FIG. 5, it has been demonstrated that the incubation time in Comparative Example 1 is 220 minutes, whereas the incubation time in Example 1 is 160 minutes, and thus the incubation time is improved (shortened) by 25 to 30%.

This is because the HBr gas was purged by the reaction between the HBr gas remaining after the etching step and the provided NH₃ gas, whereby the Br component was removed from the wafer surface.

<Experiment of Verifying Residual Amount of Etching Gas Using Ion Chromatograph and Result Thereof>

After performing etching on wafers, on which film formation is underway, using HBr gas, the inventors performed purging and film formation using the methods of various examples and comparative examples, and after the processing, the inventors conducted an experiment in which the residual concentration of Br on wafer surfaces was measured using ion chromatography.

Here, Example 2 is the case where purging was performed using NH₃ gas (380 degrees C.) and then film formation was performed. Example 3 is the case where purging was performed using H₂ gas (600 degrees C.) and then film formation was performed. Example 4 is the case where purging was performed using H₂ gas (740 degrees C.) and then film formation was performed. In contrast to Examples 2 to 4, Comparative Example 2 is the case where etching was performed for 30 minutes and purging was not performed and Comparative Example 3 is the case in which etching was performed for 60 minutes and purging was not performed. As a reference example, the residual amount of Br in the case where neither etching nor purging was carried out was also measured.

An analysis surface of a wafer as a specimen was immersed in 50 mL of ultrapure water for 3 minutes, then extracts were collected, and quantitative analysis of Br⁻ was performed on the collected extracts using ion chromatography, thereby determining the extracted amount of Br⁻. The ion chromatographic measurement conditions are represented in Table 1, and the quantitative analysis results are represented in Table 2.

TABLE 1

| | Measurement Condition |
|---|---|
| Apparatus | INTEGRION |
| | manufactured by Thermo Fisher |
| | Scientific Inc. |
| Separation Column | ∅ 2 mm × 250 mm |
| | Ion Pac AS11-HC-4μ |
| Eluent | Potassium Hydroxide/Gradient |
| Sample Injection Amount | 100 μL |
| Detector | Electric Conductivity Meter |

TABLE 2

| | Br⁻ | |
|---|---|---|
| | μg/wafer | ng/cm² |
| Reference Example | | |
| No Etching | <0.1 | <0.2 |
| No Purge | | |
| Comparative Example 2 | | |
| Etching for 30 Min. | 0.4 | 0.6 |
| No Purge | | |
| Comparative Example 3 | | |
| Etching for 60 Min. | 0.4 | 0.6 |
| No Purge | | |
| Example 2 | | |
| NH₃ Gas (380° C.) Purge | <0.1(0.09) | <0.2(0.1) |
| Example 3 | | |
| H₂ Gas (600° C.) Purge | 0.1 | 0.2 |
| Example 4 | | |
| H₂ Gas (740° C.) Purge | 0.1 | 0.2 |

Note:
μg/wafer is the component amount per wafer, and ng/cm² is the component amount per 1 cm² of the wafer. The surface area of the wafer was 707 cm². In addition, the quantitative lower limit value in this ion chromatograph measurement is 0.1 μg/wafer as the component amount per wafer and 0.2 ng/cm² as the component amount per 1 cm² of the wafer.

From Table 2, it has been demonstrated that the residual amount of Br⁻ in Examples 2 to 4 was reduced to about ⅓ with respect to the residual amount of Br⁻ in Comparative Examples 2 and 3, and the effect of reducing Br⁻ in Example 2 is high.

In addition, it has been demonstrated that, in view of the fact that in Examples 2 to 4, the residual amount of Br⁻ is almost the same as that of the reference example, in which etching was not performed at all, the Br⁻ removal effect by the purge gas such as NH₃ gas or H₂ gas is extremely high.

### <Experiment of Verifying Residual Amount of Etching Gas Using Secondary Ion Mass Spectrometry and Result Thereof>

The inventors performed etching on a wafer, on which a Si film was formed on the surface of a SiO₂ film, using HBr gas, and then performed purging and film formation using the methods of various examples and comparative examples. Then, after the processing, the residual concentration of Br on the wafer surface was measured using Secondary Ion Mass Spectrometry (SIMS). Further, the degree of roughness of the interface between an underlayer and the formed film was determined using a Transmission Electron Microscope (TEM) and an Atomic Force Microscope (AFM).

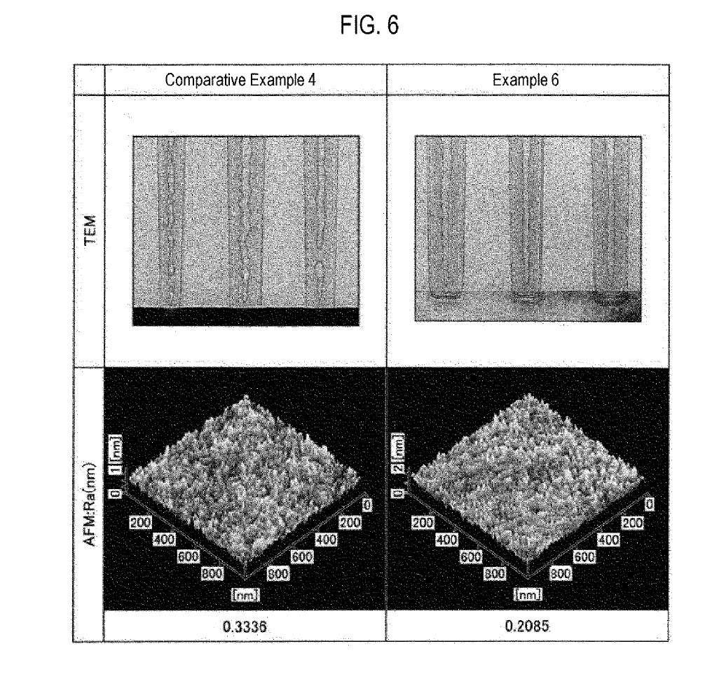

Here, Example 5 is the case where purging was performed using NH₃ gas (550 degrees C.) and then film formation was performed. Example 6 is the case where purging was performed using H₂ gas (800 degrees C.) and then film formation was performed. Comparative Example 4 is the case where purging was not performed for comparison with Examples 5 and 6. The measurement results on the residual amount of the etching gas are represented in Table 3 below. FIG. 6 represents a TEM image and an AFM image of the interface between the underlayer and the formed film.

TABLE 3

| Comparative Example 4 | Example 5 | Example 6 |
|---|---|---|
| Br Concentration | Br Concentration | Br Concentration |
| (atoms/cm³) | (atoms/cm³) | (atoms/cm³) |
| 1.60 × 10²⁰ | 3.56 × 10¹⁹ | 3.03 × 10¹⁸ |

Note: atoms/cm³ indicates the number of atoms per 1 cm³.

From Table 3, it has been demonstrated that in Example 5, the concentration of Br is reduced to about ⅕, and in Example 6, the concentration of Br is reduced to about 1/50 with respect to Comparative Example 4.

Further, from FIG. 6, it has been demonstrated that the roughness of Comparative Example 4 is Ra=0.3336 nm, whereas the roughness of Example 6 is Ra=0.2085 nm, and thus the roughness of the surface reduced by about 40%.

From the results of the various experiments described above, it has been demonstrated that both the incubation time and the roughness of the film formation surface can be improved by performing, after performing an etching step using an etching gas composed of a halogen gas, a purge step using NH₃ gas or H₂ gas, which is a purge gas reacting with the etching gas, and performing a film formation step.

According to the substrate processing method and the substrate processing system of the present disclosure, it is possible to effectively purge an etching gas from a processing container.

Other embodiments, in which other constituent elements are combined with those described in the above embodiments, may be used, and the present disclosure is not limited to the configurations described here.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing method comprising:
etching a silicon film formed on a surface of a substrate accommodated in a processing container by supplying an etching gas to the substrate;
purging the processing container by supplying a hydrogen-containing gas that reacts with the etching gas as a purge gas into the processing container; and
forming an additional silicon film on the substrate.

2. The substrate processing method of claim 1, wherein the step of etching the silicon film, the step of purging the processing container, and the step of forming an additional silicon film are performed in the same processing container.

3. The substrate processing method of claim 1, wherein the hydrogen-containing gas is selected from H₂ and NH₃.

4. The substrate processing method of claim 1, wherein the etching gas is a halogen gas.

5. The substrate processing method of claim 4, wherein the halogen gas is selected from Cl₂, HCl, HBr, and Br₂.

6. The substrate processing method of claim 1, wherein the step of forming an additional film sequentially forms a plurality of silicon films by sequentially supplying different kinds of raw material gases.

7. A substrate processing system that accommodates a substrate to form a silicon film, the substrate processing system comprising:
a processing container configured to accommodate the substrate therein;
a processing apparatus having a gas supply part configured to supply a processing gas into the processing container; and
a control device configured to control at least the gas supply part,
wherein the control device is configured to:
execute a process of etching all or a part of the silicon film by supplying an etching gas to the substrate having the silicon film on a surface thereof,
perform a process of purging by supplying a hydrogen-containing gas that reacts with the etching gas as a purge gas into the processing container, and
perform a process of forming an additional silicon film on the substrate by supplying a raw material gas to the substrate.

8. The substrate processing system of claim 7, wherein the gas supply part is configured to perform a process of sequentially forming a plurality of silicon films by sequentially supplying different kinds of raw material gases.

9. The substrate processing system of claim 7, wherein the hydrogen-containing gas is selected from H₂ and NH₃.

10. The substrate processing system of claim 7, wherein the etching gas is a halogen gas.

11. The substrate processing system of claim 10, wherein the halogen gas is selected from Cl₂, HCl, HBr, and Br₂.
